(19) United States
(12) Patent Application Publication
(10) Pub. No.: US 2015/0124425 A1
(43) Pub. Date: May 7, 2015

(54) Conductive Gasket

(71) Applicant: Cisco Technology, Inc., San Jose, CA (US)

(72) Inventors: Jing An, Shanghai (CN); Luli Gong, Shanghai (CN); Hua Yang, Shanghai (CN); Hailong Zhang, Shanghai (CN); Dewen Xu, Shanghai (CN); Susan Huang, Shanghai (CN); Mandy Hin Lam, Fremont, CA (US)

(73) Assignee: Cisco Technology, Inc., San Jose, CA (US)

(21) Appl. No.: 14/072,888

(22) Filed: Nov. 6, 2013

(51) Int. Cl. H05K 9/00

(52) U.S. Cl. CPC H05K 9/0015
USPC 361/818; 174/358

(57) ABSTRACT

An apparatus may be provided. The apparatus may comprise a core and a covering material disposed on a portion of the core. At least one opening may be disposed in the core. The at least one opening may expose at least one interior surface on the core. The at least one interior surface may be devoid of the covering material.

### TECHNICAL FIELD

The present disclosure relates generally to interference prevention.

### BACKGROUND

Electromagnetic interference (EMI) is a disturbance that affects an electrical circuit due to either electromagnetic induction or electromagnetic radiation emitted from an external source. The disturbance may interrupt, obstruct, or otherwise degrade or limit the effective performance of the circuit. These effects can range from a simple degradation of data to a total loss of data. The source may be any object, artificial or natural, that carries rapidly changing electrical currents, such as an electrical circuit.

EMI can be intentionally used for radio jamming, as in some forms of electronic warfare, or can occur unintentionally, as a result of spurious emissions for example through intermodulation products, and the like. It frequently affects the reception of AM radio in urban areas. It can also affect cell phone, FM radio and television reception, although to a lesser extent.

### BRIEF DESCRIPTION OF THE DRAWINGS

The accompanying drawings, which are incorporated in and constitute a part of this disclosure, illustrate various embodiments of the present disclosure. In the drawings:

FIG. 1 shows a device;

FIG. 2 shows an integrated connector;

FIG. 3 shows a gasket;

FIG. 4 shows a gasket on a device;

FIG. 5 shows a faceplate

FIG. 6 shows a case in which a device may be disposed; and

FIG. 7 shows a graph of radiated emissions.

### DETAILED DESCRIPTION

### Overview

An apparatus may be provided. The apparatus may comprise a core and a covering material disposed on a portion of the core. At least one opening may be disposed in the core. The at least one opening may expose at least one interior surface on the core. The at least one interior surface may be devoid of the covering material.

Both the foregoing overview and the following example embodiment are examples and explanatory only, and should not be considered to restrict the disclosure's scope, as described and claimed. Further, features and/or variations may be provided in addition to those set forth herein. For example, embodiments of the disclosure may be directed to various feature combinations and sub-combinations described in the example embodiment.

### EXAMPLE EMBODIMENTS

The following detailed description refers to the accompanying drawings. Wherever possible, the same reference numbers are used in the drawings and the following description to refer to the same or similar elements. While embodiments of the disclosure may be described, modifications, adaptations, and other implementations are possible. For example, substitutions, additions, or modifications may be made to the elements illustrated in the drawings, and the methods described herein may be modified by substituting, reordering, or adding stages to the disclosed methods. Accordingly, the following detailed description does not limit the disclosure. Instead, the proper scope of the disclosure is defined by the appended claims.

Integrated connectors may be used to interface a device to the world outside the device. When constructing the device, an Electromagnetic Interference (EMI) containment feature called a “Faraday Cage” may be designed into the device. A Faraday Cage may comprise an enclosure formed by conducting material or by a mesh of conducting material. This enclosure may block static and non-static electric fields. Consequently, a Faraday Cage may comprise an approximation to an ideal hollow conductor. Externally or internally applied electromagnetic fields produce forces on charge carriers (i.e., electrons) within the ideal hollow conductor. The charges are redistributed accordingly (e.g., electric currents may be generated). Once the charges have been redistributed so as to cancel the applied electromagnetic field inside, the currents may stop.

Embodiments of the disclosure may comprise a gasket to provide EMI shielding. Electromagnetic shielding may be the practice of reducing the electromagnetic field in a space by blocking the EMI field with barriers made of conductive or magnetic materials. Consistent with embodiments of the disclosure, for example, a conductive fabric may be added to a conductive foam core at a front, a back, a top, and a bottom side of a gasket to increase the EMI shielding performance of the gasket disposed on a device.

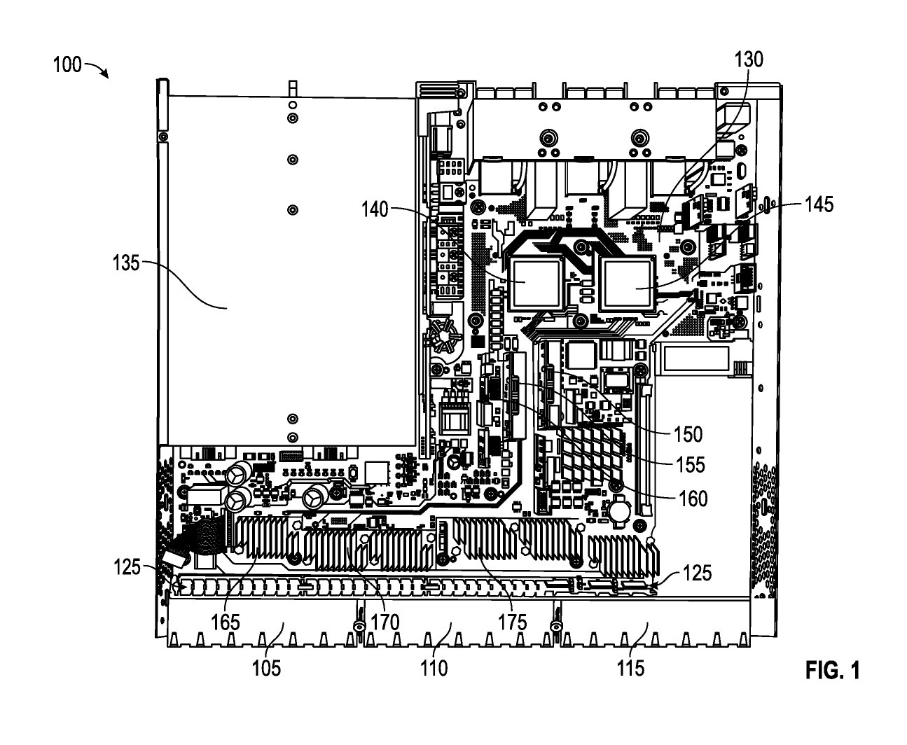

FIG. 1 shows a device 100 that may produce EMI. As shown in FIG. 1, device 100 may comprise a plurality of integrated connectors. The plurality of integrated connectors may comprise a first integrated connector 105, a second integrated connector 110, and a third integrated connector 115. A choke structure space 125 may be provided behind the plurality of integrated connectors. Choke structure space 125 may be anywhere on device 100.

As device 100 is being constructed, the plurality of integrated connectors (e.g., first integrated connector 105, second integrated connector 110, and third integrated connector 115) may be installed onto a circuit board 130 from the top and either press fit or soldered in place. Device 100 may further comprise a power supply 135.

A first application-specific integrated circuit (ASIC) 140 and a second ASIC 145 may be disposed on circuit board 130. First ASIC 140 and second ASIC 145 may comprise integrated circuits (ICs) customized for a particular use, rather than intended for general-purpose use. A plurality of direct current (DC)-to-DC converters may be included on circuit board 130. The plurality of DC-to-DC converters may comprise, but are not limited to, a first DC-to-DC converter 150, a second DC-to-DC converter 155, and a third DC-to-DC converter 160.

A plurality of physical layer (PHY) circuits may be disposed on circuit board 130. A PHY circuit may connect a link layer device (e.g., a Media Access Control, or MAC address) to a physical medium such as an optical fiber or copper cable. A PHY circuit may include a Physical Coding Sublayer (PCS) and a Physical Medium Dependent (PMD) layer. The PCS may encode and decode the data that is transmitted and received. The purpose of the encoding may be to make it easier for the receiver to recover the signal.

The plurality of PHY circuits may comprise, but are not limited to, a first PHY circuit 165, a second PHY circuit 170, and a third PHY circuit 175. First PHY circuit 165 may correspond to first integrated connector 105, second PHY circuit 170 may correspond to second integrated connector 110, and third PHY circuit 175 may correspond to third integrated connector 115.

Vertical plane members may be placed between the plurality of integrated connectors. The vertical plane members may be electrically connected to a chassis of device 100. Side fingers from the integrated connectors may be in electrical contact with the vertical plane members thus grounding the integrated connectors to the chassis and extending the Faraday Cage. Device 100 may comprise, but is not limited to, a network card, a networking device such as a router, a switch, or any type device.

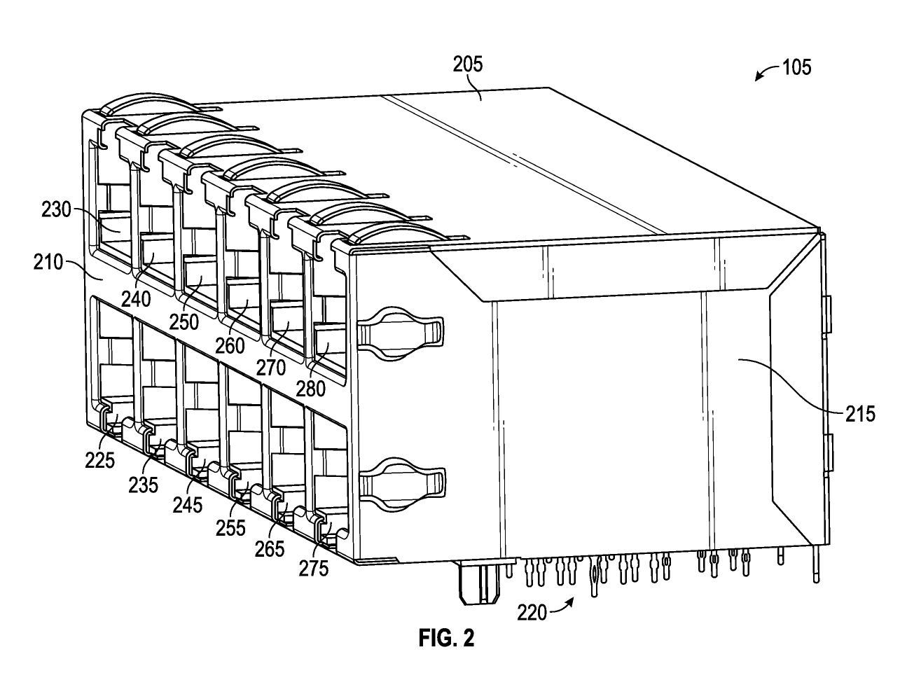

FIG. 2 shows first integrated connector 105 in more detail. As shown in FIG. 2, first integrated connector 105 may comprise a top portion 205, a front portion 210, and a side portion 215. Circuit board connectors 220 may also be included on first integrated connector 105. Front portion 210 may comprise a plurality of receptacles. The plurality of receptacles may comprise a first receptacle 225, a second receptacle 230, a third receptacle 235, a fourth receptacle 240, a fifth receptacle 245, a sixth receptacle 250, a seventh receptacle 255, an eighth receptacle 260, a ninth receptacle 265, a tenth receptacle 270, an eleventh receptacle 275, and a twelfth receptacle 280.

During operation of device 100, a plurality of jacks (e.g., RJ-45s) may be plugged into the plurality of receptacle. The plurality of receptacles may respectively connect signal wires from the plurality of jacks to ones of circuit board connectors 220. Circuit board connectors 220 may be soldered or press fit onto circuit board 130.

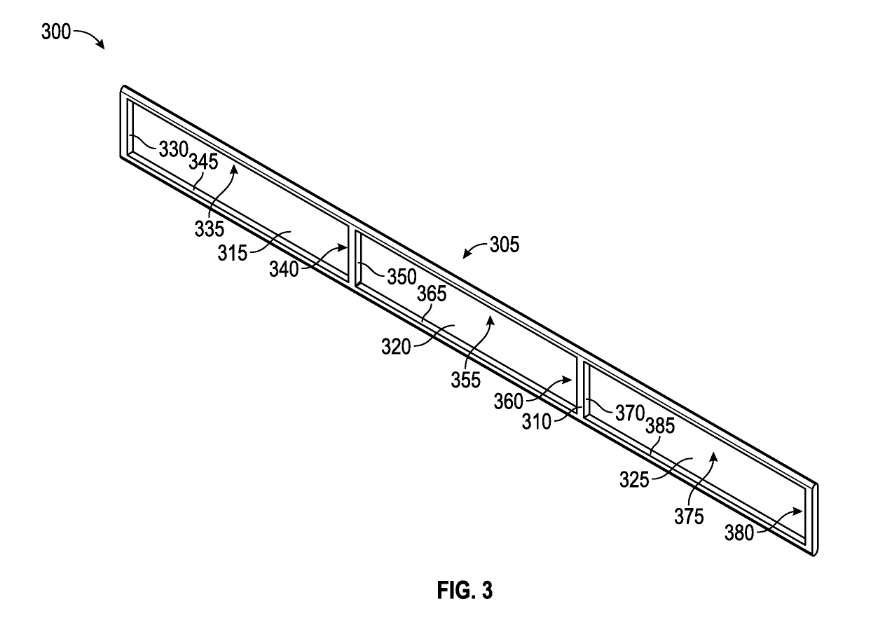

FIG. 3 shows a gasket 300. As shown in FIG. 3, gasket 300 may comprise a core 305, a covering material 310, and a plurality of openings. The plurality of openings may comprise a first opening 315, a second opening 320, and a third opening 325. While FIG. 3 shows gasket 300 as having three openings, gasket 300 is not limited to three and may have any number of openings. Furthermore, while FIG. 3 shows the plurality of openings as being rectangular, the plurality of openings are not limited to being rectangular and any of the plurality of openings may be any shape.

First opening 315 may expose a first plurality of interior surfaces. The first plurality of interior surfaces may comprise a first first interior surface 330, a second first interior surface 335, a third first interior surface 340, and a fourth first interior surface 345. Similarly, second opening 320 may expose a second plurality of interior surfaces. The second plurality of interior surfaces may comprise a first second interior surface 350, a second second interior surface 355, a third second interior surface 360, and a fourth second interior surface 365. And third opening 325 may expose a third plurality of interior surfaces. The third plurality of interior surfaces may comprise a first third interior surface 370, a second third interior surface 375, a third third interior surface 380, and a fourth third interior surface 385. While FIG. 3 shows each of the plurality of openings as having four interior surfaces, the plurality of openings are not limited to four and may have any number of interior surfaces. Also, while FIG. 3 shows the interior surfaces as being flat, the interior surfaces is not limited to being flat and may have any shape.

Core 305 may be electrically conductive and may comprise a foam material. The foam material may be electrically conductive and may comprise electrically conductive particles. For example, when core 305 is compressed, a portion of the electrically conductive particles may come into contact with each other and may create a plurality of electrical pathways through core 305. Covering material 310 may be electrically conductive and may comprise a fabric that may be electrically conductive. The fabric may be woven or non-woven. Core 305 and covering material 310 may be electrical contact with one another.

Consistent with embodiments of the disclosure, core 305 may be provided and then covered with covering material 310. The plurality of openings may then be provided in core 305 by punching core 305, for example. Providing the plurality of openings in core 305 may expose at least one interior surface on core 305. The exposed at least one interior surface may be devoid of covering material 310. In other words, a conductive fabric (e.g., covering material 310) may be added to a conductive foam core (e.g., core 305) at a front, a back, a top, and a bottom side, for example, to form gasket 300. However, the plurality interior surfaces left when the plurality of openings are formed may not be covered by the conductive fabric.

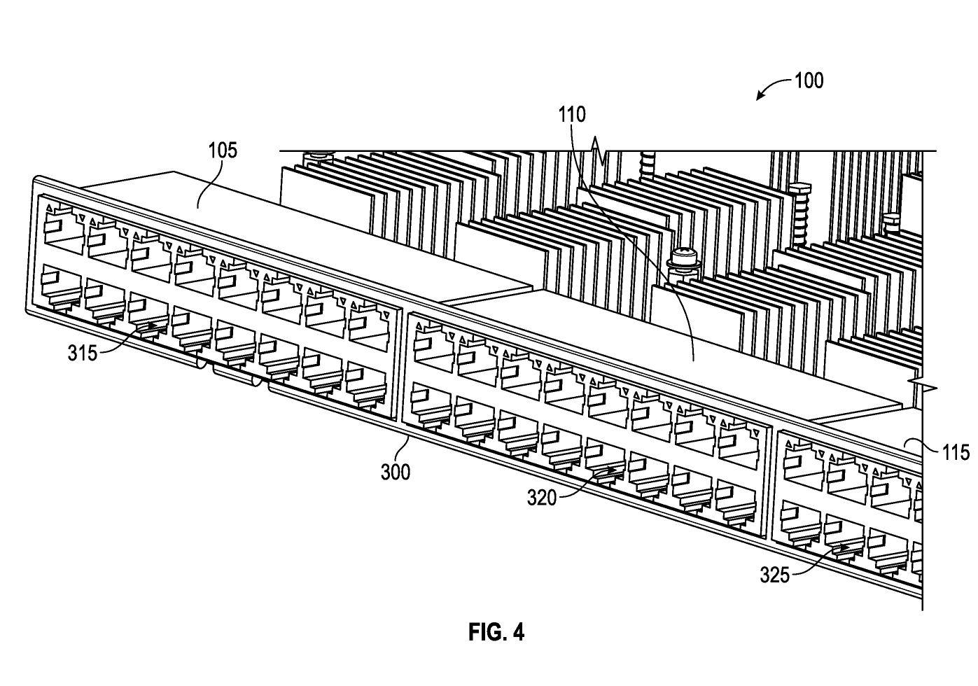

FIG. 4 shows gasket 300 disposed on device 100. As shown in FIG. 4, first integrated connector 105, second integrated connector 110, and third integrated connector 115 may be receptively disposed in first opening 315, second opening 320, and third opening 325. Consistent with embodiments of the disclosure, device 100 may comprise any number of integrated connectors and gasket 300 may comprise any number of openings. The number of openings in gasket 300 may correspond to the number of integrated connector on device 100.

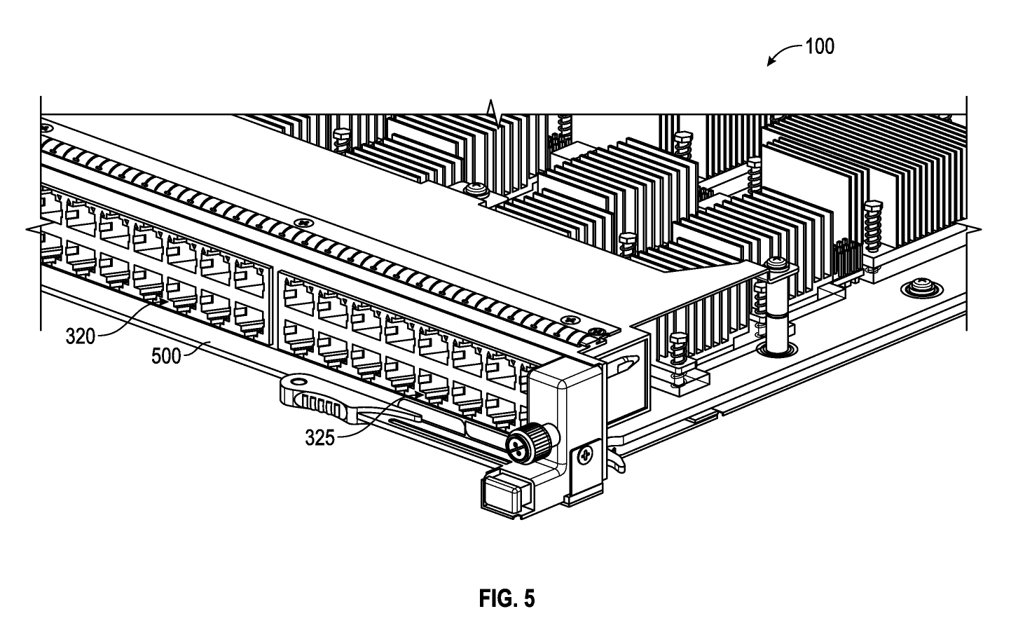

FIG. 5 shows a faceplate 500 disposed on device 100. As shown in FIG. 5, faceplate 500 may cover gasket 300. Consistent with embodiments of the disclosure, gasket 300 may be adhered to a back of faceplate 500. Consequently, gasket 300 may be disposed on device 100 as faceplate 500 is installed onto device 100.

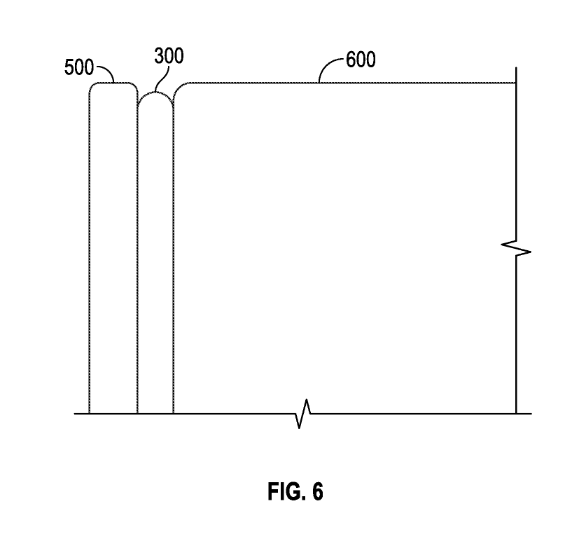

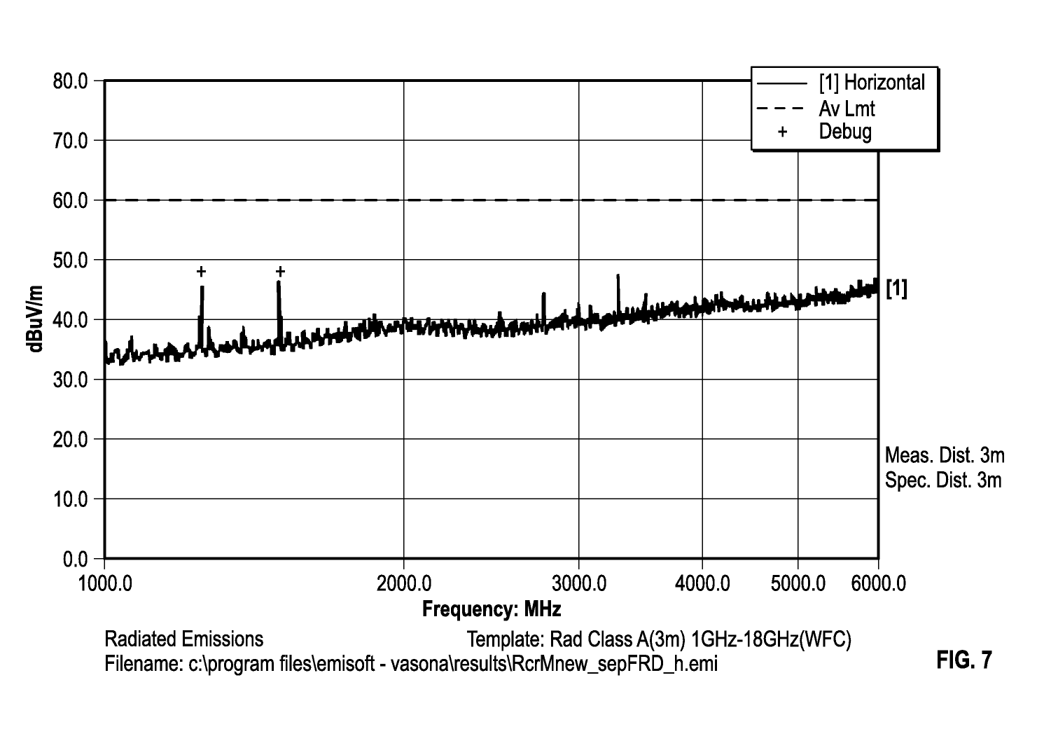

FIG. 6 shows a case 600 in which device 100 may be disposed. Case 600 may comprise, for example, a rack in which device 100 may be disposed. Case 600 may be grounded to a system ground of device 100. As shown in FIG. 6, when faceplate 500 is installed, gasket 300 may be compressed against case 600 by faceplate 500. For example, faceplate 500 may compress gasket 300 up to 40%. Core 305 in gasket 300 may be electrically conductive and may comprise a foam material. The foam material may be electrically conductive and may comprise electrically conductive particles. For example, when gasket 300 is compressed, core 305 may be compressed. When core 305 is compressed, a portion of the electrically conductive particles may come into contact with each other and may create a plurality of electrical pathways through core 305. With the combination of electrically conductive covering material 310 and electrically conductive core 305, EMI may be captured and may be conducted to ground through gasket 300. As shown in FIG. 7, radiated emissions of less than 48 dBuV/m at approximately 1.5 GHz may be realized for device 100 consistent with embodiments of the disclosure.

Embodiments of the present disclosure, for example, are described above with reference to block diagrams and/or operational illustrations of methods, systems, and computer program products according to embodiments of the disclosure. The functions/acts noted in the blocks may occur out of the order as shown in any flowchart. For example, two blocks shown in succession may in fact be executed substantially concurrently or the blocks may sometimes be executed in the reverse order, depending upon the functionality/acts involved.

While the specification includes examples, the disclosure's scope is indicated by the following claims. Furthermore, while the specification has been described in language specific to structural features and/or methodological acts, the claims are not limited to the features or acts described above. Rather, the specific features and acts described above are disclosed as example for embodiments of the disclosure.

What is claimed is:

1. An apparatus comprising:
a core;
a covering material disposed on a portion of the core; and
at least one opening disposed in the core, the at least one opening exposing at least one interior surface on the core, the at least one interior surface being devoid of the covering material.

2. The apparatus of claim 1, wherein the core is electrically conductive.

3. The apparatus of claim 1, wherein the core comprises foam.

4. The apparatus of claim, 1 wherein the core comprises electrically conductive foam.

5. The apparatus of claim 1, wherein the foam comprises electrically conductive particles.

6. The apparatus of claim 1, wherein the covering material is electrically conductive.

7. The apparatus of claim 1, wherein the covering material comprises fabric.

8. The apparatus of claim 1, wherein the covering material comprises electrically conductive fabric.

9. The apparatus of claim 1, wherein the at least one opening is rectangular.

10. An apparatus comprising:
a case;
a faceplate; and
a gasket disposed between the case and the faceplate, the gasket being compressed between the case and the faceplate, the gasket comprising:
a covering material disposed on a core, the covering material being electrically conductive and the core being electrically conductive; and
at least one opening disposed in the core, the at least one opening exposing at least one interior surface on the core, the at least one interior surface being devoid of the covering material.

11. The apparatus of claim 10, wherein the gasket is compressed at least 40%.

12. The apparatus of claim 10, further comprising an integrated connector disposed in the at least one opening.

13. The apparatus of claim 10, further comprising an integrated connector disposed in the at least one opening, an exterior surface of the integrated connector fitting snuggly against the at least one interior surface on the core.

14. The apparatus of claim 10, wherein the apparatus has radiated emissions of less than 48 dBuV/m at approximately 1.5 GHz.

15. The apparatus of claim 10, wherein the core is foam.

16. The apparatus of claim 10, wherein the foam comprises electrically conductive particles.

17. The apparatus of claim 10, wherein the covering material comprises fabric.

18. The apparatus of claim 10, wherein the at least one opening is rectangular.

19. The apparatus of claim 10, wherein the case encloses a networking device.

20. The apparatus of claim 19, wherein the networking device comprises one of the following: a network switch and a router.

21. An apparatus comprising:
an electrically conductive covering material disposed on an electrically conductive core, the core comprising a foam material; and
a plurality of openings disposed in the core, the plurality of openings exposing a plurality of interior surfaces on the core.

22. The apparatus of claim 21, wherein the core comprises electrically conductive particles.

23. The apparatus of claim 21, wherein the covering material comprises fabric.

24. The apparatus of claim 21, wherein the covering material comprises a woven fabric.

25. The apparatus of claim 21, wherein the covering material comprises a non-woven fabric.

26. The apparatus of claim 21, wherein the plurality of interior surfaces are devoid of the covering material.

27. The apparatus of claim 21, wherein each of the plurality of openings are rectangular.

28. The apparatus of claim 21, wherein the apparatus is disposed in a networking device.
